(19) United States
(12) Patent Application Publication
(10) Pub. No.: US 2002/0127806 A1
(43) Pub. Date: Sep. 12, 2002

(54) Method of forming multiple gate oxide layers with different thicknesses in one ion implantation process

(76) Inventor: Wei-Wen Chen, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/682,826

(22) Filed: Oct. 23, 2001

(30) Foreign Application Priority Data
Mar. 9, 2001 (TW) 090105626

(51) Int. Cl. H01L 21/8234

(52) U.S. Cl. 438/275

(57) ABSTRACT

The present invention provides multiple gate oxide layers with different thicknesses on a semiconductor substrate in an oxygen ion implantation process. The semiconductor substrate comprises a silicon surface, comprising at least a first area and a second area. A first mask layer, having a first opening to expose portions of the silicon surface in the first area, is formed on the silicon surface to cover surfaces of both the first area and the second area. An oxygen ion implantation process is then performed to implant oxygen ions with a predetermined concentration into the first area through the first opening. Then the first mask layer is removed. Finally, an oxidation process is performed to simultaneously form a silicon oxide layer with a first predetermined thickness on portions of the silicon surface in the first area and a silicon oxide layer with a second predetermined thickness on portions of the silicon surface in the second area.

### BACKGROUND OF INVENTION

1. Field of the invention

The present invention relates to a method of forming multiple gate oxide layers with different thicknesses in one ion implantation process, and more specifically, to a method of forming multiple gate oxide layers with different thicknesses in one oxygen ion implantation process.

2. Description of the Prior Art

In the semiconductor industry, metal-oxide-semiconductor (MOS) transistors are widely used as on/off switches that control the input or output of digital information. A MOS transistor comprises a gate, with an underlying gate oxide layer, a source and drain (S/D) and a silicon substrate. When a voltage applied to the gate exceeds a threshold voltage, strong inversion occurs and a channel is formed on the surface of the silicon substrate under the gate oxide layer. When the MOS transistor is switched on, current from the drain flows to the source through the channel. With the enormous advances made in the manufacturing technology of integrated circuits (ICs), what were once separate electrical circuits designed for different purposes are now frequently embedded on a single semiconductor chip, i.e. an embedded semiconductor chip. Such embedded semiconductor chips comprise many MOS transistors with different functions and different threshold voltages. For example, the threshold voltage of the gates in periphery I/O circuits is 3.3 volts while the threshold voltage of the gates in core circuitry is 1.5 volts.

One of the approaches used to adjust threshold voltages is to form gate oxide layers with different thicknesses. The gate oxide layer is generally formed using a thermal oxidation process. The quality of the gate oxide layer significantly influences the electrical properties of its associated MOS transistor, such as the threshold voltage and the breakdown voltage. However, it is difficult to ensure the quality of the gate as the thickness of the gate oxide layer shrinks. As a result, there is a need to improve the prior art method so as to form a better gate oxide layer.

Please refer to FIG. 1 to FIG. 3 of cross-sectional views of forming silicon oxide layers 16 and 19, both used as gate oxide layers, with different thicknesses on a semiconductor substrate, 10 according to the prior art. As shown in FIG. 1, the semiconductor substrate 10, normally a silicon substrate, comprises a first area 22 and a second area 24 separated by a shallow trench 14. As shown in FIG. 2, a first lithography process is performed to form a photoresist layer 12 on the surface of the semiconductor substrate 10 to cover the first area 22 and expose the second area 24. An ion implantation process is performed on the second area 24 and then the photoresist layer 12 is removed. A thermal oxidation process, normally a dry-wet-dry (DWD) thermal oxidation process, is then performed to form a silicon oxide layer 16 on the surface of the second area 24. The DWD thermal oxidation process, with an operational temperature of about 900 to 1100° C., is normally performed for 6 to 8 hours in a furnace with an oxygen supply.

As shown in FIG. 3, a second lithography process is performed to form a photo resist layer 18 to cover the second area 24 and expose the surface of portions of the semiconductor substrate 10 in the first area 22. A thermal oxidation process is then performed in a furnace to form the silicon oxide layer 19, having a thickness different from that of the silicon oxide 16, on the surface of portions of the semiconductor substrate in the first area 22.

However, gate oxide layers are normally formed by performing a furnace oxidation process, with a process time of 6 to 7 hours for each batch, according to the prior art. Two or three lithography processes using different photoresist layers are needed to expose different areas, with an oxidation process performed on each area, respectively, so as to form gate oxide layers with different thicknesses. The manufacturing leadtime is thus increased and the production efficiency is consequently impacted.

### SUMMARY OF INVENTION

It is therefore a primary object of the present invention to provide a method of forming multiple gate oxide layers with different thicknesses so as to improve the production efficiency.

It is another object of the present invention to provide a method of forming multiple gate oxide layers with different thicknesses by performing an oxygen ion implantation process.

According to the claimed invention, a method is provided to form multiple gate oxide layers with different thicknesses on a semiconductor substrate in an oxygen ion implantation process. The semiconductor substrate comprises a silicon surface, further comprising at least a first area and a second area separated by shallow trenches. At the beginning of the method, a first mask layer is formed on the silicon surface to cover surfaces of both the first area and the second area. The first mask layer is then defined and patterned to form a first opening in the first mask layer so as to expose portions of the silicon surface in the first area. An oxygen ion implantation process is performed to implant oxygen ions with a predetermined concentration into the first area via the first opening and the first mask layer is removed thereafter. Finally, an oxidation process is performed to simultaneously form a silicon oxide layer with a first predetermined thickness on portions of the silicon surface in the first area and a silicon oxide layer with a second predetermined thickness on portions of the silicon surface in the second area.

It is an advantage of the present invention against the prior art that an oxygen ion implantation process is performed to form a doped area in portions of the silicon surface having a thickness less than 100 angstroms. The thickness of the gate oxide layer is thus increased in the subsequent thermal oxidation process. In addition, the production leadtime is reduced due to the simultaneous formation of multiple gate oxide layers with different thicknesses. Thus the production efficiency is significantly improved.

These and other objectives of the present invention will no doubt become obvious to those of ordinary skill in the art after reading the following detailed description of the preferred embodiment, which is illustrated in the multiple figures and drawings.

### BRIEF DESCRIPTION OF DRAWINGS

FIG. 1 to FIG. 3 are the cross-sectional views of forming silicon oxide layers with different thicknesses on a semiconductor substrate according to the prior art.

FIG. 4 to FIG. 6 are the cross-sectional views of forming silicon oxide layers with different thicknesses on a semiconductor substrate according to the present invention.

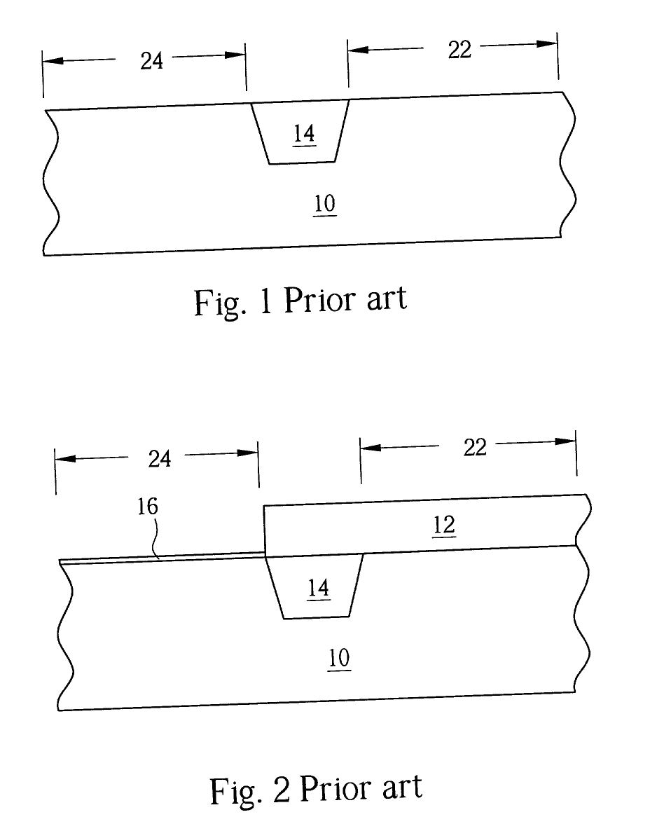

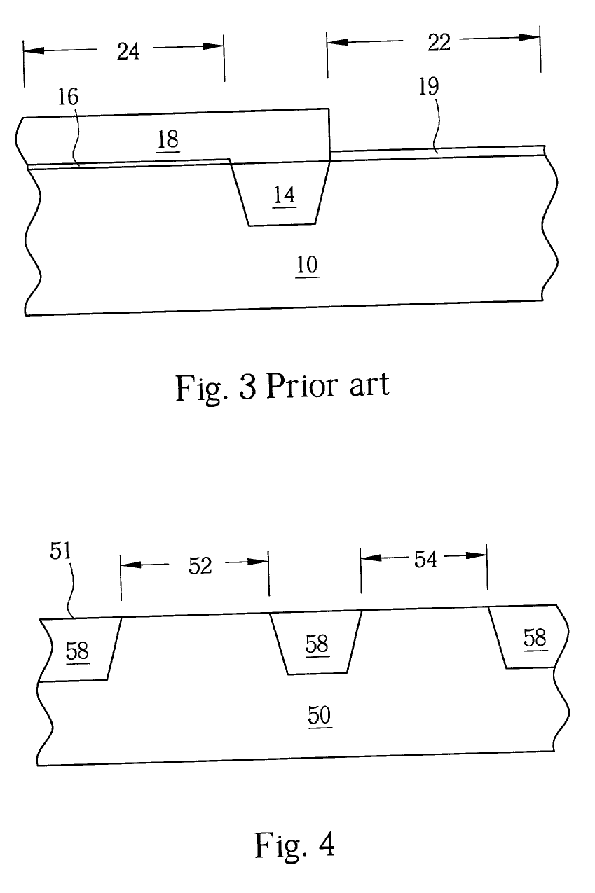

### DETAILED DESCRIPTION

Please refer to FIG. 4 to FIG. 6 of cross-sectional views of forming silicon oxide layers 62 and 63, both used as gate oxide layers, with different thicknesses on a semiconductor substrate 50 according to the present invention. As shown in FIG. 4, a semiconductor substrate 10 comprises a silicon surface 51, further comprising at least a first area 52 and a second area 54 separated by shallow trenches 58. In subsequent processes, the first area 52 is used for the formation of the silicon oxide layer 62 thicker than the silicon oxide layer 63 in the second area.

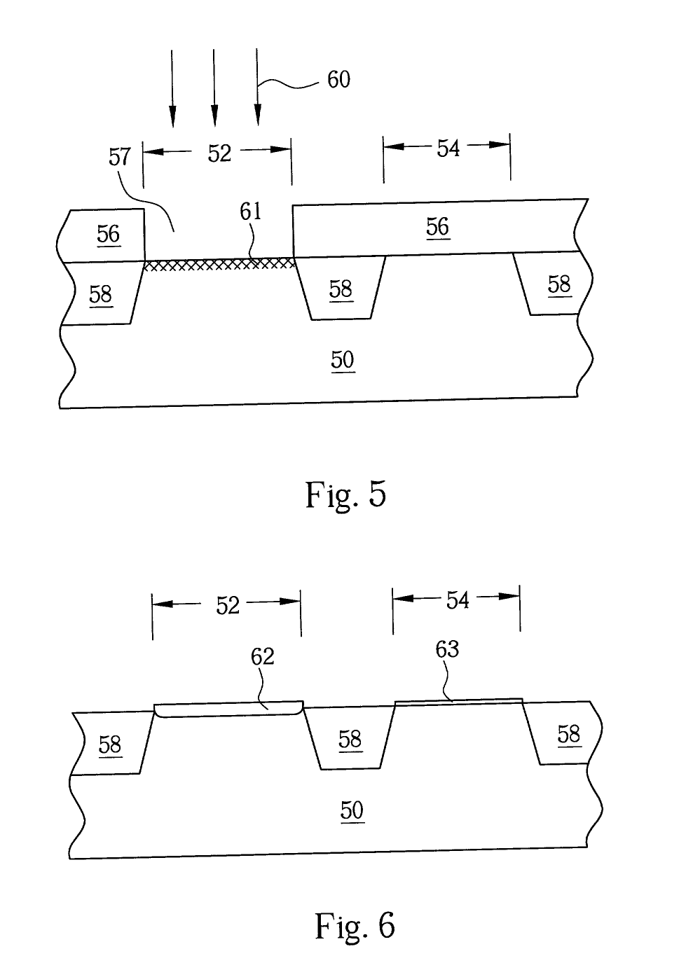

As shown in FIG. 5, a first photoresist layer 56 is formed on the silicon surface 51 to cover surfaces of both the first area 52 and the second area 54. The first photoresist layer 56 is then defined and patterned to form a first opening 57 in the first photoresist layer 56 so as to expose portions of the silicon surface 51 in the first area 52. An oxygen ion implantation process 60 is performed to implant oxygen ions 61 with a predetermined concentration into the first area 52 via the first opening 57. In the preferred embodiment of the present invention, the predetermined concentration of the oxygen ions 61 in the oxygen ion implantation process 60 ranges from 1×10²⁰ to 1×10²² atoms/cm³. The first photoresist layer 56 is removed thereafter.

As shown in FIG. 6, an oxidation process, a dry furnace oxidation process with an operational temperature ranging from 700 to 950° C., is performed to simultaneously form the silicon oxide layer 62 with a first predetermined thickness on portions of the silicon surface 51 in the first area 52 and the silicon layer 63 with a second predetermined thickness on portions of the silicon surface 51 in the second area 54.

In the preferred embodiment of the present invention, an implantation dosage in the oxygen ion implantation process 60 ranges from 1×10¹⁵ to 1×10¹⁶ cm⁻² , with an implantation energy ranging from 200 eV to 5 KeV. An preferred implantation dosage in the oxygen ion implantation process 60 is about 1×10¹⁶ cm⁻² , with an implantation energy of about 200 eV, so that more than 80% of the oxygen ions 61 distribute in portions of the silicon surface 51 having a thickness of approximately 50 angstroms.

In comparison with the prior art, the oxygen ion implantation process 60 is employed in the present invention to form a doped area of the oxygen ions 61 in portions of the silicon surface 51 having a thickness less than 100 angstroms. The thickness of the silicon oxide layer 62 is thus increased in the subsequent thermal oxidation process. Besides, in another embodiment of the present invention, more than two gate oxide layers can be simultaneously formed on portions of the silicon surfaces with different oxygen dosage and portions of the silicon surface without oxygen dosage, respectively, by performing a thermal oxidation process.

Those skilled in the art will readily observe that numerous modifications and alterations of the device may be made while retaining the teachings of the invention. Accordingly, the above disclosure should be construed as limited only by the metes and bound of the appended claims.

What is claimed is:

1. A method of forming multiple gate oxide layers with different thicknesses on a semiconductor substrate in an oxygen ion implantation process, the semiconductor substrate comprising a silicon surface, the silicon surface comprising at least a first area and a second area separated by shallow trenches, the method comprising:
forming a first mask layer on the silicon surface to cover surfaces of both the first area and the second area;
defining and patterning the first mask layer to form a first opening in the first mask layer so as to expose portions of the silicon surface in the first area;
performing an oxygen ion implantation process to implant oxygen ions with a predetermined concentration into the first area through the first opening;
removing the first mask layer; and
performing an oxidation process to simultaneously form a silicon oxide layer with a first predetermined thickness on portions of the silicon surface in the first area and with a second predetermined thickness on portions of the silicon surface in the second area.

2. The method of claim 1 wherein the second predetermined thickness is greater than the first predetermined thickness.

3. The method of claim 1 wherein the predetermined concentration ranges from 1×10²⁰ to 1×10²² atoms/cm³.

4.The method of claim 1 wherein an implantation dosage in the oxygen ion implantation process ranges from 1×10¹⁵ to 1×10phu 16 cm^{31 2}, with an implantation energy ranging from 200 eV to 5 KeV.

5. The method of claim 1 wherein an implantation dosage in the oxygen ion implantation process is about 1×10¹⁶ cm⁻², with an implantation energy of about 200 eV, so that more than 80% of the oxygen ions distribute in portions of the silicon surface having a thickness of approximately 50 angstroms.

6. The method of claim 1 wherein the first mask layer is composed of a photoresist.

7. The method of claim 1 wherein the oxidation process is a dry furnace oxidation process, with an operational temperature ranging from 700 to 950° C.

8. A method of forming multiple silicon oxide layers with different thicknesses, the method comprising:
providing a semiconductor substrate comprising a silicon surface, the silicon surface comprising at least a first area and a second area;
implanting oxygen ions with a first predetermined concentration and with a second predetermined concentration into portions of the silicon surface in the first area and the second area, respectively; and
performing an oxidation process to form a first silicon oxide layer, having a first predetermined thickness, on portions of the silicon surface in the first area, and to simultaneously form a second silicon oxide layer, having a second predetermined thickness, on portions of the silicon surface in the second area.

9. The method of claim 8 wherein the first predetermined thickness is unequal to the second predetermined thickness.

10. The method of claim 8 wherein the first predetermined concentration ranges from 1×10¹⁹ to 1×10²² atoms/cm³.

11. The method of claim 8 wherein the second predetermined concentration ranges from 1×10¹⁹ to 1×10²² atoms/cm³.

12. The method of claim 8 wherein an implantation dosage of the oxygen ions ranges from 1×10¹⁵ to 1×10¹⁶ cm^{31 2}, with an implantation energy ranging from 200 eV to 5 KeV.

13.The method of claim 8 wherein an implantation dosage of the oxygen ions is about 1×10¹⁶ cm⁻², with an implantation energy of about 200 eV, so that more than 80% of the oxygen ions distribute in portions of the silicon surface having a thickness of approximately 50 angstroms.

14.The method of claim 8 wherein the oxidation process is a dry furnace oxidation process, with an operational temperature ranging from 700 to 950° C.
